(19) United States
(12) Patent Application Publication
(10) Pub. No.: US 2025/0364285 A1
(43) Pub. Date: Nov. 27, 2025

(54) MONITOR SYSTEM AND OPERATION METHOD THEREOF

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Lin MA, Shanghai City (CN); Honghua ZHU, Shanghai City (CN); Lei CHEN, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/732,440

(22) Filed: Jun. 3, 2024

(30) Foreign Application Priority Data
May 21, 2024 (CN) 202410629345.7

(51) Int. Cl. H01L 21/67

(52) U.S. Cl. CPC H01L 21/67201; H01L 21/67259

(57) ABSTRACT

A system is provided and includes a lift shaft having a platform and an indicator extending along a shaft portion of the lift shaft. The system further includes a first sensor generating, according to a position of the indicator, a mapping start detection signal; a detection circuit detecting a voltage level of the mapping start detection signal to record a first time; and at least one second sensor generating, according to positions of a plurality of wafers in a wafer carrier on the platform, at least one mapping signal to the detection circuit. The detection circuit detects a voltage level of the mapping signal to record a second time for monitoring operations of the lift shaft.

### CROSS REFERENCE

The present application claims priority to China Application Serial Number 202410629345.7 filed on May 21, 2024, which is herein incorporated by reference in its entirety.

### BACKGROUND

In semiconductor fabrication facility, the tool's vacuum arm orchestrates the meticulous transfer of wafers from the load lock chamber to diverse process chambers. Primarily, the vacuum arm governs alterations in the wafer's horizontal disposition, while the vertical Z-axis movement is effectuated through the load lock's stepping motor and intricately engineered mechanical structure. This procedural intricacy assumes paramount significance in semiconductor manufacturing, underpinning the precision required for successive processing stages within distinct chambers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a manufacturing system, in accordance with various embodiments of the present disclosure.

FIG. 2 is a schematic diagram of a cluster-type architecture, in accordance with various embodiments of the present disclosure.

FIG. 3A is a schematic diagram of part of a load lock chamber, in accordance with various embodiments of the present disclosure.

FIG. 3B is a schematic diagram of part of a platform corresponding to FIG. 3A, in accordance with various embodiments of the present disclosure.

FIG. 4 is a schematic diagram of part of a load lock chamber, in accordance with various embodiments of the present disclosure.

FIG. 5A is a schematic diagram of a detection circuit, a sensor, and an indicator corresponding to FIG. 3A, in accordance with various embodiments of the present disclosure.

FIG. 5B is a schematic diagram of an indicator corresponding to FIG. 5A, in accordance with various embodiments of the present disclosure.

FIG. 6 is a flow chart of a method of operating a manufacturing system, in accordance with some embodiments.

FIG. 7 depicts schematic diagrams of operations of the lift shaft, in accordance with some embodiments.

FIG. 8 illustrates that voltage level of the mapping signal verses time, in accordance with some embodiments of the present disclosure.

FIG. 9 depicts schematic diagrams of position deviation results, in accordance with some embodiments.

FIG. 10 is a schematic diagram of a detection circuit, in accordance with various embodiments of the present disclosure.

FIG. 11 is a schematic diagram of input/output devices, in accordance with various embodiments of the present disclosure.

FIG. 12 is a schematic diagram of voltage follower circuits, in accordance with various embodiments of the present disclosure.

FIG. 13 is a schematic diagram of a power supply circuit, in accordance with various embodiments of the present disclosure.

FIG. 14 is a schematic diagram of a filter circuit, in accordance with various embodiments of the present disclosure.

FIG. 15 is a schematic diagram of a crystal oscillator circuit, in accordance with various embodiments of the present disclosure.

FIG. 16 is a schematic diagram of a control unit rest circuit, in accordance with various embodiments of the present disclosure.

FIG. 17 is a schematic diagram of a communication circuit, in accordance with various embodiments of the present disclosure.

FIG. 18 is a schematic diagram of a registered jack, in accordance with various embodiments of the present disclosure.

FIG. 19 is a schematic diagram of a signal transmission indicator circuit, in accordance with various embodiments of the present disclosure.

FIG. 20 is a schematic diagram of a control unit, in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

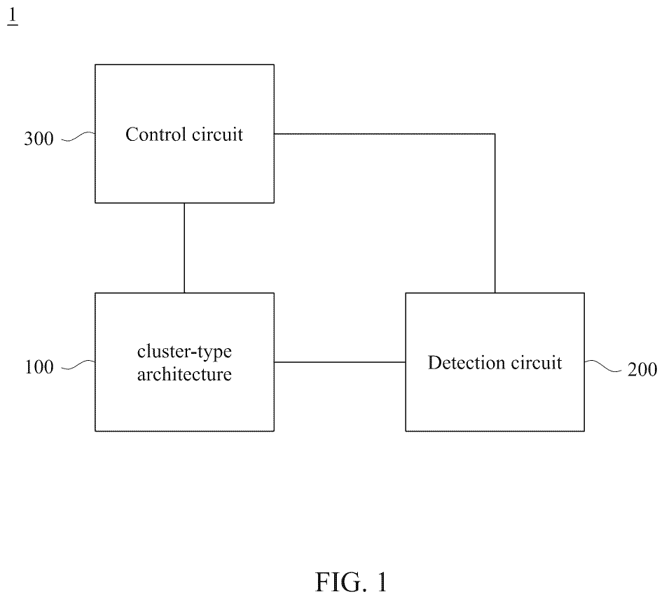

Reference is now made to FIG. 1. FIG. 1 is a schematic diagram of a manufacturing system 1, in accordance with various embodiments of the present disclosure. For illustration, the manufacturing system 1 includes a cluster-type architecture 100, a detection circuit 200, and a control circuit 300. In some embodiments, the cluster-type architecture 100 and the detection circuit 200 are coupled to the control circuit 300 and communicate with the control circuit 300 through the network interface including wireless network interfaces, such as BLUETOOTH, WIFI, WIMAX, GPRS, or WCDMA, and wired network interfaces such as ETHERNET, USB, or IEEE-1364 in manufacturing processes performed to multiple wafers in lots. In some embodiments, the cluster-type architecture 100 is controlled in response to commands received from the detection circuit 200. The detection circuit 200 is electrically coupled to the cluster-type architecture 100 and configured to fetch signals indicating manufacturing parameters of the cluster-type architecture 100 in the manufacturing processes.

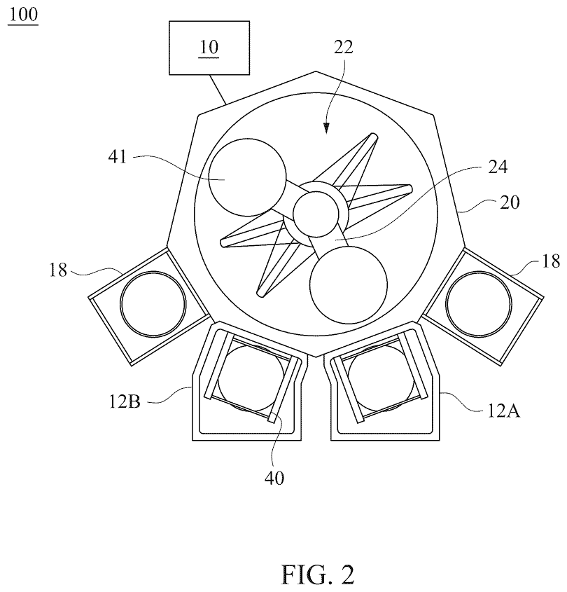

Reference is now made to FIG. 2. FIG. 2 is a schematic diagram of the cluster-type architecture 100 corresponding to FIG. 1, in accordance with various embodiments of the present disclosure.

In some embodiments, the cluster-type architecture 100 facilitates integration of the multiple process steps (e.g., the chemical vapor deposition, etching and other processes used in the formation of integrated circuits on the wafers) and improve wafer manufacturing throughput. The cluster-type architecture 100 includes a controller 10 to control the components therein in response to command, associated with processes being performed to the wafers, from the control circuit 300. For example, the controller 10 in the cluster-type architecture 100 is a general-purpose computing device including a hardware processor and a non-transitory, computer-readable storage medium. Storage medium, amongst other things, is encoded with, i.e., stores, computer program code (instructions), i.e., a set of executable instructions. In some embodiments, the computer program code is configured to cause the cluster-type architecture 100 to be usable for performing a portion or all of the noted processes and/or methods in processing the wafers. In one or more embodiments, the hardware processor and the control circuit 300 include a central processing unit (CPU), a multi-processor, a distributed processing system, an application specific integrated circuit (ASIC), and/or a suitable processing unit.

As illustratively shown in FIG. 2, the cluster-type architecture 100 includes load lock chambers 12A and 12B, multiple chambers 18 and a central transfer chamber 20. In some embodiments, the chambers 18 includes process chamber(s) disposed around the central transfer chamber 20 equipped with a wafer transport system 22 for transporting the wafers among the load lock chambers 12A, 12B and the multiple chambers 18. The configurations of FIG. 2 are given for illustrative purposes. Various implements are within the contemplated scope of the present disclosure. For example, in some embodiments, the cluster-type architecture 100 includes more than two chambers 18.

In some embodiments, the wafer transport system 22 is implemented by a transfer robot.

In some embodiments, each of the load lock chambers 12A and the 12B is configured to receive a wafer carrier (cassette or holder) 40 holding multiple (semiconductor) wafers 41. In some embodiments, the chambers 18 include an orientation chamber and a cooldown chamber, and the load lock chambers 12A and 12B are flanked by the orientation chamber and the cooldown chamber, as shown in the embodiments of FIG. 2.

Process chambers in the chambers 18 for carrying out various processes in the fabrication of integrated circuits on the wafers 41 are positioned with the orientation chamber, the cooldown chamber, and the load lock chambers 12A and 12B around the central transfer chamber 20. The wafer transport system 22 in the central transfer chamber 20 is fitted with a transfer blade 24.

In some embodiments, the transfer blade 24 is implemented by vacuum arms that are configured to move the wafer 41 in the horizontal direction (e.g., on x-y plane). The transfer blade 24 is configured to receive and to support the individual wafers 41 from the wafer carrier 40 in each of the load lock chambers 12A and 12B. The wafer transport system 22 is capable of rotating the transfer blade 24 in the clockwise or counterclockwise direction in the central transfer chamber 20, and the transfer blade 24 can extend or retract to facilitate placement and removal of the wafers 41 in and from the load lock chambers 12A and 12B, the orientation chamber, the cooldown chamber and the process chambers 18.

According to some embodiments, in operation, for example, the load lock chamber 12A is controlled to move vertically (e.g., z direction) the wafer carrier 40 to set the selected wafer 41 in the wafer carrier 40 to an accessible level for the transfer blade 24 in the central transfer chamber 20. Then, the transfer blade 24 initially removes the wafer 41 from the wafer carrier 40 and then inserts the wafer 41 in the one of the chambers 18, for example, the orientation chamber. The wafer transport system 22 then transfers the wafer 41 from the orientation chamber to one or more of the process chambers, where the wafer 41 is subjected to a chemical vapor deposition or other process.

When the manufacturing process is complete, the wafer transport system 22 transfers the wafer 41 from the process chamber to the cooldown chamber, and ultimately, back to the wafer carrier 40 in the load lock chamber 12A. In some embodiments, after moving the wafer 41 out from the cooldown chamber, the wafer transport system 22 transfers the wafer 41 to the wafer carrier 40 in another load lock chamber 12B.

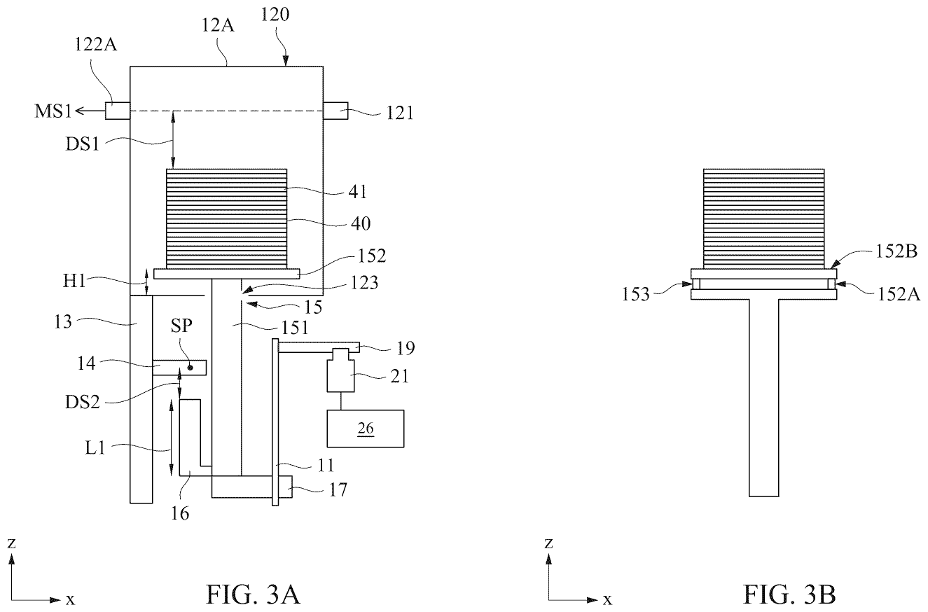

Reference is now made to FIG. 3A. FIG. 3A is a schematic diagram of part of the load lock chamber 12A, in accordance with various embodiments of the present disclosure. In some embodiments, the configurations of the load lock chamber 12B are similar to the load lock chamber 12A. Hence, the repetitious descriptions are omitted here.

As illustratively shown in FIG. 3A, the load lock chamber 12A includes a chamber wall 120 defining a chamber interior. The load lock chamber 12A further includes an emitter 121 and at least one light sensor 122A that are equipped on the chamber wall 120 outside of the chamber interior. The emitter 121 and the light sensor 122A aligns with each other along horizontal direction (e.g., x direction.)

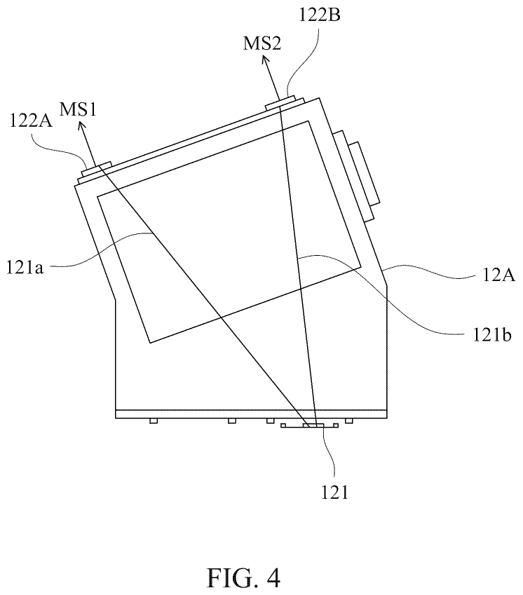

In some embodiments, as shown in FIG. 4 depicting a schematic diagram of part of the load lock chamber 12A, the load lock chamber 12A further includes a light sensor 122B arranged on the same side of the load lock chamber 12A along with the light sensor 122A. The emitter 121 is situated on opposite sides of the load lock chamber 12A and configured to emit light beam 121a to the light sensor 122A and light beam 121b to the light sensor 122B.

In some embodiments, with reference to both FIGS. 3A and 4, the emitter 121, the light sensor 122A and 122B are configured to monitor the positions of the wafers 41 in the wafer carrier 40, and the light sensors 122A and 122B are configured to generate mapping signals MS1 and MS2 to the detection circuit 200 according to positions of the wafers 41. In some embodiments, the light sensors 122A and 122B transmit the mapping signals MS1 and MS2 through the controller 10 of FIG. 2. For example, when the wafer 41 in the wafer carrier 40 blocks the light beams 121a and/or 121b, the light sensors 122A and 122B adjust, for example, decrease voltages on the mapping signals MS1 and MS2 correspondingly. On contrary, when the light sensors 122A and 122B receive the light beams 121a and/or 121b, which indicates that no wafer 41 is between the light sensors 122A-122B and the emitter 121, the light sensors 122A and 122B transmit the mapping signals MS1 and MS2 having voltages greater than a threshold voltage VTH correspondingly.

The configurations of FIG. 4 are given for illustrative purposes. Various implements are within the contemplated scope of the present disclosure. For example, in some embodiments, the load lock chamber 12A includes a pair of the emitter 121 and only one light sensor 122A (or the light sensor 122B).

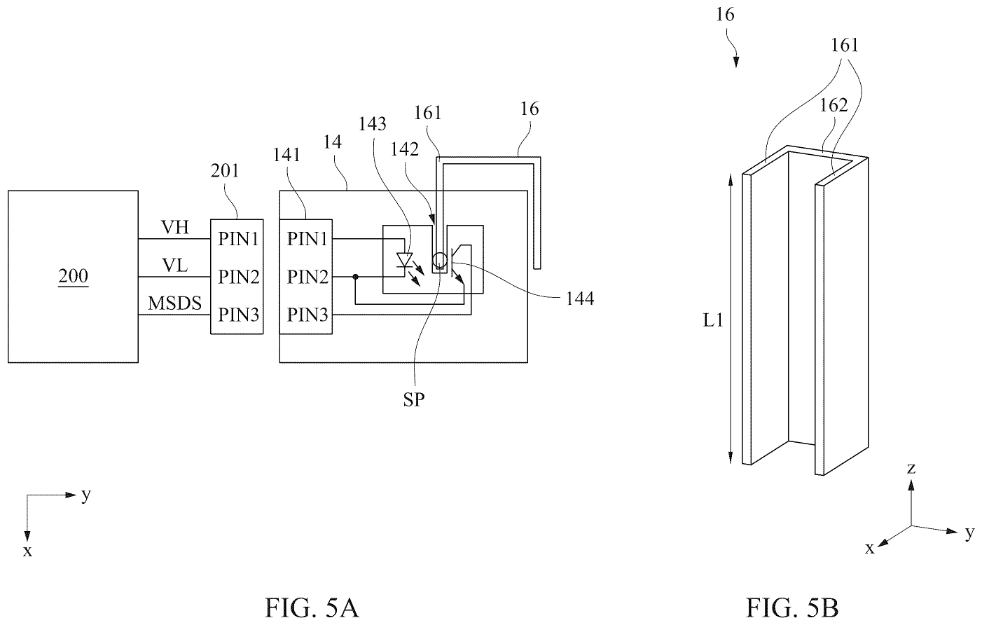

With reference to FIG. 3A again, the load lock chamber 12A is sustained by a chamber frame 13. For the sake of simplicity, only part of the chamber frame 13 is depicted in FIG. 3A. The cluster-type architecture 100 further includes a sensor 14 that is attached to the chamber frame 13 and below the chamber wall 120. Detailed configurations of the sensor 14 will be discussed with reference to FIG. 5A.

In the embodiments of FIG. 3A, the cluster-type architecture 100 further includes a lift shaft 15 below the chamber wall 120. The lift shaft 15 includes a shaft portion 151 and a platform 152. The shaft portion 151 extends in y direction. The platform 152 is mounted on an upper end of the lift shaft 15 (i.e., the platform 152 arranged on a top of the shaft portion 151). In some embodiments, the shaft portion 151 extends through a shaft opening 123 provided in the bottom of the load lock chamber 12A.

As shown in FIG. 3B which depicts the platform 152 corresponding to FIG. 3A, in accordance with various embodiments of the present disclosure, the platform 152 includes a bottom stage 152A and an upper stage 152B that are parallel to each other along x direction. The bottom stage 152A and the upper stage 152B are physically connected with each other by connect portions 153. In some embodiments, the connect portions 153 includes screws. In various embodiments, the connection portions 153 includes springs. In the embodiments of FIG. 3A, the wafer carrier 40 is placed on the upper stage 152B.

The lift shaft 15 further includes an indicator 16 that is coupled to the shaft portion 151 and extend parallel to the shaft portion 151 along z direction. In some embodiments, the indicator 16 is coupled with the shaft portion 151 through a connector (e.g., a bearing through which the shaft portion 151 passes), so that the indicator 16 moves upward or downward along with the shaft portion 151 and the platform 152.

In some embodiments, the lift shaft 15 is configured to adjust the height of the platform 152 along z direction in the load lock chamber 12A. For example, during operation of the cluster-type architecture 100, the wafer carrier 40 is supported by the platform 152. The lift shaft 15 raises the platform 152 from an initial height H1 and the wafer carrier 40 in the load lock chamber 12A, to align the wafers 41 with a slot (not shown, arranged above the emitter 121 and the light sensor 122A along z direction) provided in the chamber wall 120. The transfer blade 24 of the wafer transport system 22 extends through the slot to transfer the wafers 41 from and load the wafers 41 onto the wafer carrier 40.

Specifically, the cluster-type architecture 100 further includes a connector 17, a rotation screw 11, a belt 19, a shaft elevation motor 21, and a power supply and controller 26. The connector 17 is coupled to the lift shaft 15. The rotation screw 11 connects the connector 17 to the belt 19. The belt 19 is controlled by the shaft elevation motor 21. According to some embodiments, the power supply and controller 26 supplies power to trigger the shaft elevation motor 21 based on commands to lift the platform 152 from the controller 10 of FIG. 2. An axis, engaged to belt 19, of the shaft elevation motor 21 rotates and the belt 19 moves accordingly to spin the rotation screw 11. The connector 17 engaged with the bottom of the shaft portion 151 rotates the shaft portion 151 to raise and lower the lift shaft 15. Alternatively stated, the spiral motion is converted into the vertical motion to transfer the wafers 41.

In some embodiments, as illustratively shown in FIG. 3A, the lowest height of the platform 152 in the load lock chamber 12A is the height H1, while the lift shaft 15 is at the load position. The distance between the top of the wafer carrier 40 and position where the light sensor 122A senses the light emitted from the emitter 121 is DS1. The indicator 16 has a length LI along the z direction. When the platform 152 situates at the lowest height H1, the top end of the indicator 16 is away from a sensing point SP of the sensor 14 by a distance DS2, the distance DS2 being smaller than the distance DS1, according to some embodiments.

Reference is now made to FIG. 5A. FIG. 5A is a schematic diagram of the detection circuit 200, the sensor 14, and the indicator 16 corresponding to FIG. 3A, in accordance with various embodiments of the present disclosure.

As shown in FIG. 5A, the detection circuit 200 is coupled to the sensor 14 through an input/output (I/O) device 201 including three pins PIN1 to PIN3. The sensor 14 includes an I/O device 141 including three pins PIN1 to PIN3 coupled correspondingly to the pins PIN1 to PIN3 of the input/output device 201. The detection circuit 200 is configured to transmit a voltage VH through the pins PIN1 of the I/O devices 201 and 141, and to transmit a voltage VL through the pins PIN2 of the I/O devices 201 and 141. The sensor 14 is configured to transmit a mapping start detection signal MSDS to the detection circuit 200 through the pins PIN3 of the I/O devices 201 and 141.

With reference to both FIGS. 5A and 5B, the indicator 16 includes flange portions 161 and a web portion 162, having C shaped cross section on xy plane. In some embodiments, one flange portion 161 extends in x direction to align to an opening 142 of the sensor 14, in which the opening 142 extends in x direction and is interposed between a light emitter 143 and a receiver 144 of the sensor 14, as shown in FIG. 5A.

For illustration, the light emitter 143 has a first terminal coupled to the pin PIN1 of the I/O device 141 and a second terminal coupled to the pin PIN2 of the I/O device 141. A first terminal of the receiver 144 is coupled to the second terminal of the light emitter 143, and a second terminal of the receiver 144 is coupled to the pin PIN3 of the I/O device 141.

In some embodiments of operation, the sensor 14 is configured to generate the mapping start detection signal MSDS according to a position of the indicator 16. For example, with reference to FIGS. 3A and 5A, when the lift shaft 15 is at the load position, the upper portion (e.g., top) of the indicator 16 is below the sensing point SP, and the light emitted from the light emitter 143 is received by the receiver 144. The receiver 144 is conducted and generates the mapping start detection signal MSDS having the voltage VL, for example, a ground voltage.

On the other hand, when the lift shaft 15 moves upward to set the indicator 16 to reach the sensing point SP of the sensor 14, the receiver 144 generates the mapping start detection signal MSDS having the voltage VH greater than the voltage VL in response to the light emitted from the light emitter 143 being blocked by the flange portion 161.

According to some embodiments, the present application provides a method 600 of operating the manufacturing system 1 to check whether the position of the platform 152 along z direction shifts in the manufacturing process, preventing the manufacturing system 1 from wafer scrapped cases induced by malposition of the wafers.

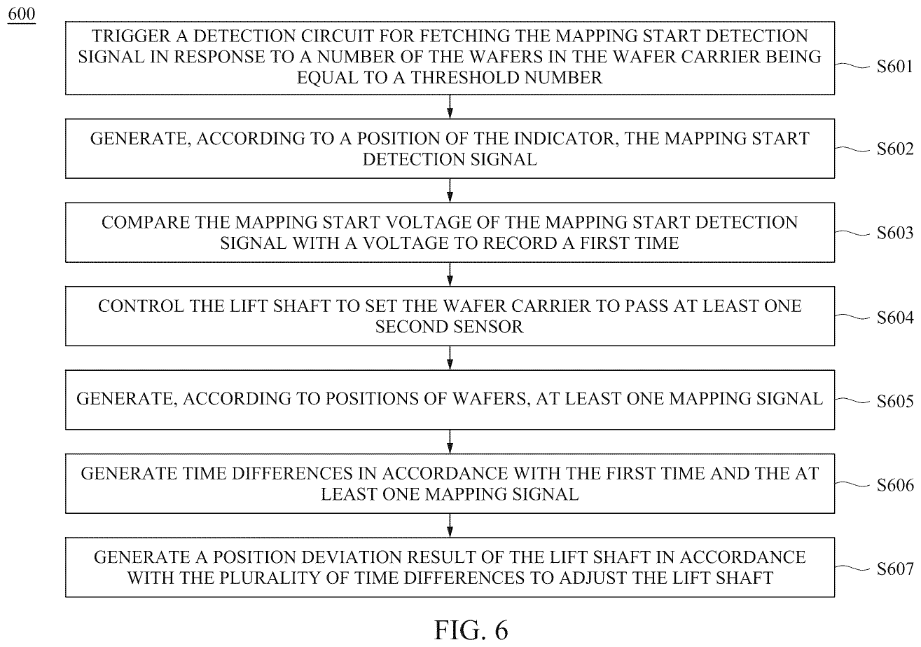

Reference is now made to FIG. 6. FIG. 6 is a flow chart of the method 600 of operating the manufacturing system 1, in accordance with some embodiments. It is understood that additional operations/stages can be provided before, during, and after the processes shown by FIG. 6, and some of the operations/stages described below can be replaced or eliminated, for additional embodiments of the method 600. The method 600 includes operations S601-S607 and will be discussed in the following paragraphs with reference to FIGS. 1-9.

In operation S601, the control circuit 300 of FIG. 1 checks a number of wafers 41 in the current wafer carrier 40 based on a manufacturing data associated with the current wafer carrier 40, and generates a control signal, in response to the number of wafers 41 in the current wafer carrier 40 being equal to a threshold number, to the detection circuit 200 to trigger the detection circuit 200 for fetching the mapping start detection signal MSDS from the sensor 14. For example, in some embodiments, when the threshold number is 25 and the wafer carrier 40 is full packed to include a number of 25 wafers, the control circuit 300 sends to the control signal including commands of initiation of mapping operation to the detection circuit 200. On the other hand, when the number of the wafer 41 in the wafer carrier 40 is not equal to the threshold number (i.e., there are empty slots in the wafer carrier 40,) the detection circuit 200 does not fetch mapping start detection signal MSDS from the sensor 14. Alternatively stated, the detection circuit 200 enters an idle mode and performs no action.

With reference to FIGS. 3A, 5A and 7, the lift shaft 15 is initially at the load position during the stage 701. During the stage 702, the lift shaft 15 is controlled to move upward along z direction with a velocity VC during the stage 702.

In operation S602, the sensor 14 generates the mapping start detection signal MSDS according to the position of the indicator 16. For example, during the stage 702, the sensor 14 generates the mapping start detection signal MSDS having the voltage VH when the indicator 16 passes through the sensor 14.

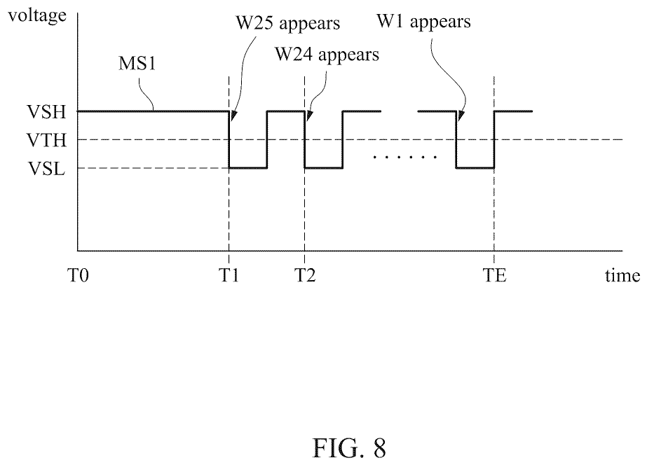

In operation S603, the detection circuit 200 detects and compares the voltage level of the mapping start detection signal MSDS with the voltage VH to record a time TO. In some embodiments, when the voltage level of the mapping start detection signal MSDS equals to the voltage VH, the detection circuit 200 records the current time as time TO as shown in FIG. 8 and starts counting time from time TO.

During operation S604, the lift shaft 15 is controlled to raise the platform 152 and to set the wafer carrier 40 to pass the light sensor 122A and/or the light sensor 122B.

In some embodiments, with reference to FIGS. 4, 7 and 8, during operation S605, the light sensor 122A and/or the light sensor 122B generates the mapping signal MS1 and/or the mapping signal MS2 according to the positions of wafers 41 in the load lock chamber 12A.

For example, when the wafers 41 block the light sensor 122A and/or the light sensor 122B, the light sensor 122A and/or the light sensor 122B generates the mapping signal MS1 and/or the mapping signal MS2 that have voltage levels smaller than the threshold voltage VTH. As shown in FIG. 8, the wafer W25, one closest to the light sensor 122A of the wafers 41, in the wafer carrier 40 blocks the light emitted from the emitter 121, and the light sensor 122A correspondingly adjusts the voltage level of the mapping signal MS1 from a voltage VSH to a voltage VSL smaller than the threshold voltage VTH at mapping time T1. The configurations of and analysis to the mapping signal MS2 generated by the light sensor 122B by the detection circuit 200 are similar to the mapping signal MS1 generated by the light sensor 122A. Hence, the repetitious descriptions are omitted here.

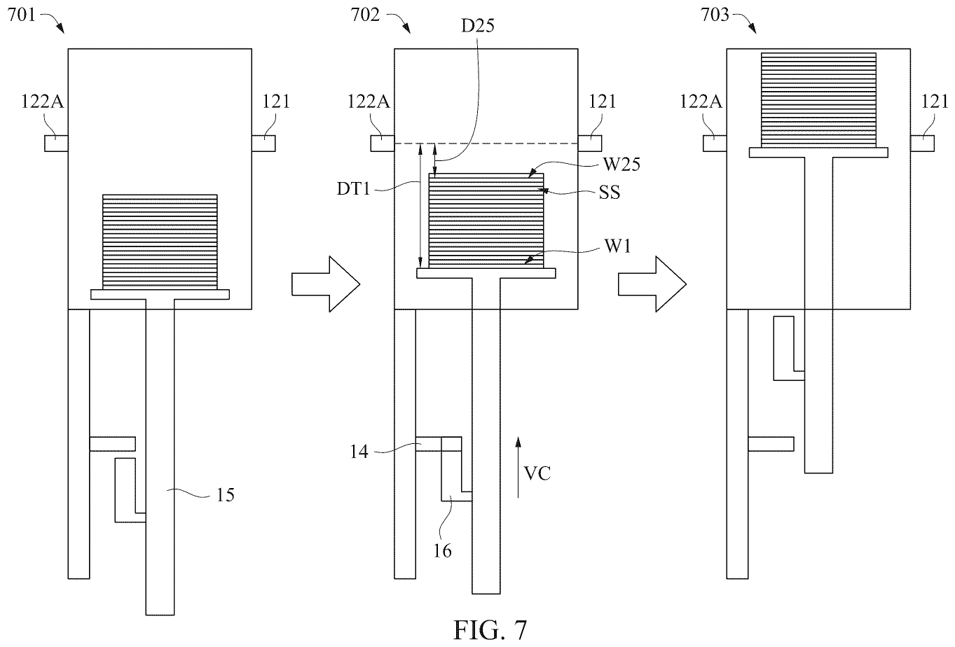

On the other hand, when spaces SS, as shown in FIG. 7, between the wafers 41 pass the light sensor 122A and/or the light sensor 122B, the light sensor 122A and/or the light sensor 122B generates the mapping signal MS1 and/or the mapping signal MS2 that have voltage levels greater than the threshold voltage VTH. As shown in FIG. 8, the space SS between the wafers W24-W25 does not block the light emitted from the emitter 121, and the light sensor 122A correspondingly adjusts the voltage level of the mapping signal MS1 from the voltage VSL to the voltage VSH greater than the threshold voltage VTH after mapping time T1.

In operation S606, the detection circuit 200 generates time differences between time TO and the mapping times in response to a voltage level of the mapping signal being detected to be less than the threshold voltage VTH. For example, the detection circuit 200 detects the voltage levels of the mapping signal MS1 and/or MS2 to record mapping times for monitoring the operations of the lift shaft 15. In some embodiments, the detection circuit 200 receives the mapping signal MS1 from the light sensor 122A and records the mapping time T1 in response to detecting the first drop, corresponding to the wafer W25, of the voltage level of the mapping signal MS1 to a voltage below the threshold voltage VTH. Furthermore, the detection circuit 200 generates a time difference ΔT25 between time T0 and the mapping time T1 by deducting time TO from the mapping time T1 and further transmits the time difference ΔT25 to the control circuit 300.

Similarly, from the stage 702 to the stage 703 as all the wafers in the wafer carrier 40 pass the light sensors 122A-122B, the detection circuit 200 records the mapping times T2-T25 in response to detecting the drops, corresponding in sequence to the wafers W24-W1, of the voltage level of the mapping signal MS1 to a voltage below the threshold voltage VTH. Furthermore, the detection circuit 200 generates time differences ΔT24-ΔT1 between time T0 and the mapping times T2-T25 by deducting time TO from the mapping times T2-T25 separately and further transmits the time differences ΔT24-ΔT1 to the control circuit 300.

In addition, as shown in FIG. 8, an ending time TE is recorded by the detection circuit 200 when the voltage level of the mapping signal MS1 is detected to be greater than the threshold voltage VTH after the wafer W1 appears. The detection circuit 200 further correspondingly terminates detecting the mapping signal MS1.

In operation S607, the control circuit 300 generates a position deviation result of the lift shaft 15 in accordance with the time differences to adjust the lift shaft 15.

Specifically, in some embodiments, the control circuit 300 calculates a distance according to one of the time differences and the velocity of the lift shaft 15. For example, with references to FIGS. 7-8, the control circuit 300 derives the distance DT25, that the wafer W25 travels from an initial position to the position where the light sensor 122A senses the wafer 25, according to equation (1) as below:

$$DT 25 = VC \times Δ T 25 \qquad ( 1 )$$

Furthermore, the control circuit 300 records the distance DT25 and compares the distance DT25 with a threshold value to generate the position deviation result, in which the threshold value corresponds to a tolerance of position shift of the platform 152 along z direction. In some embodiments, when the distance DT25 is greater than the threshold value, the control circuit 300 generates the position deviation result indicating that the lift shaft 15 malfunctions (e.g., the lift shaft 15 is tilted).

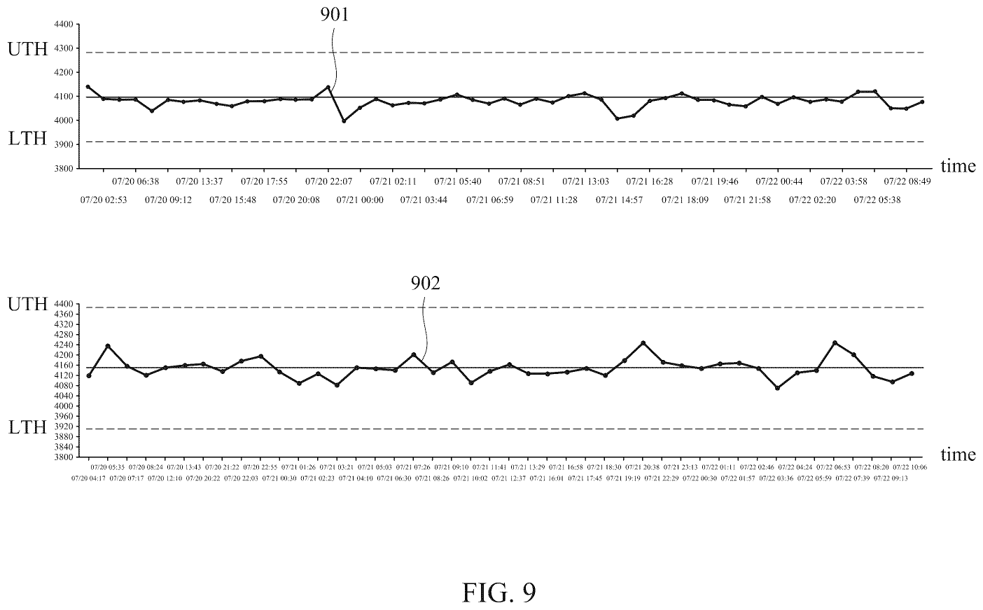

In some various embodiments, the control circuit 300 compares the distance with a threshold range to generate the position deviation result. For instance, as shown in FIG. 9, a threshold range in distance along z direction from an upper threshold value UTH and a bottom threshold value LTH is depicted in the position deviation result in a form of chart. The lines 901 and 902 indicate the aforementioned distances corresponding various wafer carrier 40 being transferred by the lift shaft 15. In some embodiments, the lines 901 and 902 correspond to the lift shaft 15 in the load lock chambers 12A and 12B of FIG. 2 respectively. In some embodiments, when the data of the lines 901-902 are within the threshold range, it indicates that the lift shaft 15 functions well and no adjustment is required.

In some approaches, monitoring the operations of the lift shaft in the load lock chamber is performed by checking the move steps of shaft elevation motor. For example, the move steps of the shaft elevation motor is detected by an encoder coupled to the shaft elevation motor, and the number of detected move steps is compared with a default number by the encoder to determine whether the shaft elevation motor. However, it excludes position shift of platform of the lift shaft induced by the malfunctions of the belt, the rotation screw and loose of the load lock stage screws/springs, as shown in FIG. 3B.

Compared with the approaches, with the configurations of the present application, the operations of the lift shaft is carefully monitored by the real-time system which compares the detected distances with standard values during transferring wafers. By checking the position deviation result, proper adjustments can be made to malfunctioning components of the cluster-type architecture 100, for example, the load lock stage screws/springs, reducing the wafer scrap risk and improving yields of manufacture.

In various embodiments, the control circuit 300 calculates distances DT1-DT25 according to the time differences ΔT1-ΔT25 and the velocity of the lift shaft 15 separately according to equation (2) as below:

$$DT = VC \times Δ T \qquad ( 2 )$$

in which DT corresponds to one of the distance between a corresponding wafer to the position where the light sensor 122A or 122B senses the wafer, and ΔT corresponds to a time difference between time T0 and a corresponding mapping time.

Furthermore, the control circuit 300 records the distances DT1-DT25 and compares each of the distances DT1-DT25 with a corresponding one of a plurality of threshold ranges to generate the position deviation result. Each of the threshold ranges corresponds to one of the wafers 41 in the wafer carrier 40.

In some embodiments, when all of the distances DT1-DT25 are within the threshold ranges, the control circuit 300 generates the position deviation result indicating that the lift shaft 15 operates properly. In various embodiments, when one or more than more distances DT1-DT25 is out of the threshold ranges, the position deviation result indicates that the lift shaft 15 does not operate properly and needs to be adjusted.

In various embodiments, the control circuit 300 calculates portions of the distances DT1-DT25 and compares portions of the distances DT1-DT25 with corresponding ones of the threshold ranges to generate the position deviation result.

The configurations of FIGS. 1-9 are given for illustrative purposes. Various implements are within the contemplated scope of the present disclosure. For example, in some embodiments, the load lock chamber 12A has only one light sensor 122A and the detection circuit 200 only detects the mapping signal MS1. In various embodiments, the load lock chamber 12A has two light sensors 122A-122B. The detection circuit 200 detects both the mapping signals MS1-MS2 and calculates two groups of the time differences correspondingly. The control circuit 300 further calculates corresponding distances based on two groups of the time differences and generates the position deviation result based on the distances. In some embodiments, as the light sensors 122A-122B situate at different positions, adjustments can be made to different components according to the position deviation result.

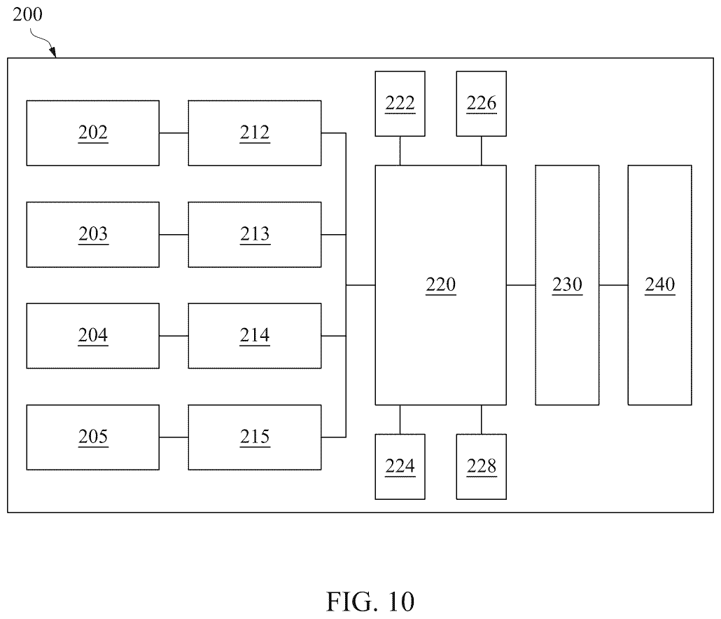

Reference is now made to FIG. 10. FIG. 10 is a schematic diagram of the detection circuit 200, in accordance with various embodiments of the present disclosure. For illustration, the detection circuit 200 includes input/output devices 202-205, voltage follower circuits 212-215, a detection circuit 200, a power supply circuit 222, a filter circuit 224, a crystal oscillator circuit 226, a control unit rest circuit 228, a communication circuit 230, and a registered jack 240. Each of the input/output devices 202-205 is coupled to a corresponding one of the voltage follower circuits 212-215. The voltage follower circuits 212-215 are coupled between the input/output devices 202-205 and the control unit 220. The control unit 220 is further coupled to the power supply circuit 222, the filter circuit 224, the crystal oscillator circuit 226, the control unit rest circuit 228, and the communication circuit 230. The communication circuit 230 is further coupled to the registered jack 240. In some embodiments, the detection circuit 200 is coupled to the control circuit 300 through the registered jack 240.

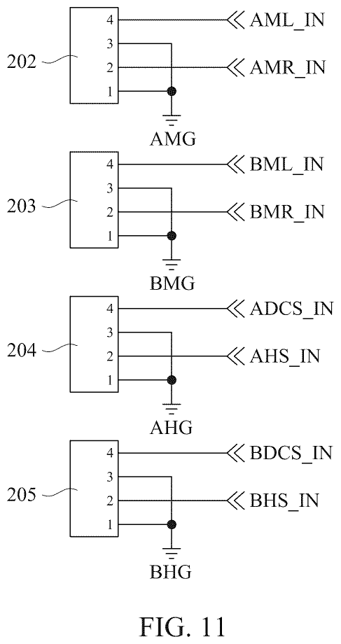

Reference is now made to FIG. 11. FIG. 11 is a schematic diagram of the input/output devices 202-205, in accordance with various embodiments of the present disclosure. In some embodiments, the input/output device 202 is coupled to the light sensors 122A-122B of the load lock chamber 12A of FIG. 2 and configured to transmit signals AML_IN and AMR_IN that are configured with respect to the mapping signals MS1 and MS2 of FIG. 4 respectively. Similarly, the input/output device 203 is coupled to the light sensors 122A-122B of the load lock chamber 12B of FIG. 2 and configured to transmit signals BML_IN and BMR_IN that are configured with respect to the mapping signals MS1 and MS2 of FIG. 4 respectively.

The input/output device 204 is coupled to the sensor 14 of FIG. 3A attached to the load lock chamber 12A to receive and to transmit the mapping start detection signal MSDS as a signal AHS_IN. In some embodiments, the input/output device 204 further receives and transmits a signal ADCS_IN indicating that a door (not shown) on the load lock chamber 12A is close. Similarly, the input/output device 205 is coupled to the sensor 14 attached to the load lock chamber 12B to receive and to transmit the mapping start detection signal MSDS as a signal BHS_IN. In some embodiments, the input/output device 205 further receives and transmits a signal BDCS_IN indicating that a door (not shown) on the load lock chamber 12B is close.

In some embodiments, the input/output devices 202-205 are implemented by pluggable terminal blocks.

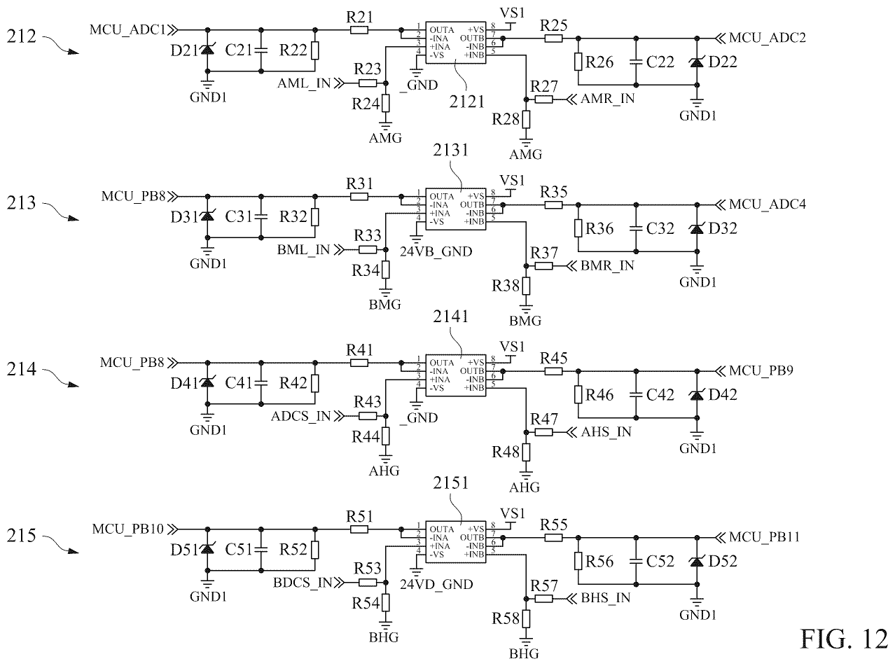

Reference is now made to FIG. 12. FIG. 12 is a schematic diagram of the voltage follower circuits 212-215, in accordance with various embodiments of the present disclosure. For illustration, the voltage follower circuit 212 includes an operational amplifier 2121. The first and second pins of the operational amplifier 2121 is coupled to a resistor R21, and the resistor R21 further coupled to first terminals of a resistor R22, a capacitor C21 and a diode D21, in which second terminals of the resistor R22, the capacitor C21 and the diode D21 are grounded. The third pin of the operational amplifier 2121 is coupled to first terminals of resistors R23-R24, a second terminal of the resistor R23 receives the signal AML_IN, and a second terminal of the resistor R24 is grounded. The fourth pin of the operational amplifier 2121 is grounded. The fifth pin of the operational amplifier 2121 is coupled to first terminals of resistors R27-R28, a second terminal of the resistor R27 receives the signal AMR_IN, and a second terminal of the resistor R28 is grounded. The sixth and seventh pins of the operational amplifier 2121 is coupled to a resistor R25, and the resistor R25 further coupled to first terminals of a resistor R26, a capacitor C22 and a diode D22, in which second terminals of the resistor R26, the capacitor C22 and the diode D22 are grounded. The eighth pin of the operational amplifier 2121 is coupled to a supply voltage. In some embodiments, the operational amplifier 2121 is configured to generate signals MCU_ADC1 and MCU_ADC2 in response to the signals AMR_IN and AML_IN.

The configurations of the voltage follower circuits 212-215 are similar to the voltage follower circuit 212. Hence, the repetitious descriptions are omitted here.

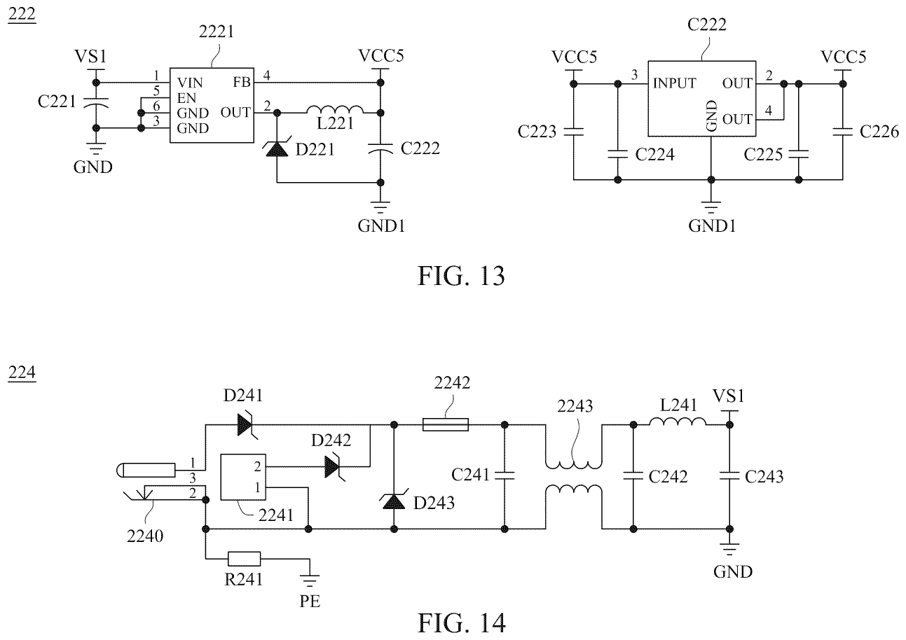

Reference is now made to FIG. 13. FIG. 13 is a schematic diagram of the power supply circuit 222, in accordance with various embodiments of the present disclosure. For illustration, the power supply circuit 222 includes a regulator 2221 and a low dropout voltage regulator 2222. The first pin of the regulator 2221 is coupled to the supply voltage. A capacitor C221 is coupled between the ground and the supply voltage, in which the third, fifth, and sixth pins of the regulator 2221 are grounded. The second pin of the regulator 2221 is coupled to first terminals of an inductor L221 and a diode D221. The second terminal of the inductor L221 is coupled to the fourth pin of the regulator 2221 at a supply voltage terminal VCC5. A capacitor C222 is coupled between the supply voltage terminal VCC5 and the ground GND1. An input pin of the low dropout voltage regulator 2222 is coupled to first terminals of capacitors C2223-C2224 at the supply voltage terminal VCC5. Second terminals of the capacitors C2223-C2224 are coupled to the ground GND1 and a ground pin of the low dropout voltage regulator 2222. The second and fourth pins of the low dropout voltage regulator 2222 are coupled together to first terminals of capacitors C225-C226 at the supply voltage terminal VCC5. Second terminals of the capacitors C225-C226 are coupled to ground GND1. In some embodiments, the power supply circuit 222 is configured to provide supply power voltages to the control unit 220.

Reference is now made to FIG. 14. FIG. 14 is a schematic diagram of the filter circuit 224, in accordance with various embodiments of the present disclosure. The filter circuit 224 includes a power jack 2240 to receive power supply, a terminal block 2241, a fast recovery rectifier 2242, and a common mode choke 2243. For illustration, the first pin of the power jack 2240 is coupled to a diode D241. The second and third pins of the power jack 2240 are coupled to a ground PE through a resistor R241. The first pin of the terminal block 2241 is coupled to a diode D243, a capacitor C241, and the common mode choke 2243. The second pin of the terminal block 2241 is coupled to the diode D243 and the fast recovery rectifier 2242 through a diode D242. The fast recovery rectifier 2242 is further coupled to the capacitor C241 and the common mode choke 2243. The other terminals of the common mode choke 2243 are coupled to a capacitor C242 and an inductor L241. The inductor L241 is coupled to supply voltage VS1 and a capacitor C243. The capacitors C242 and C243 are further coupled to the ground GND.

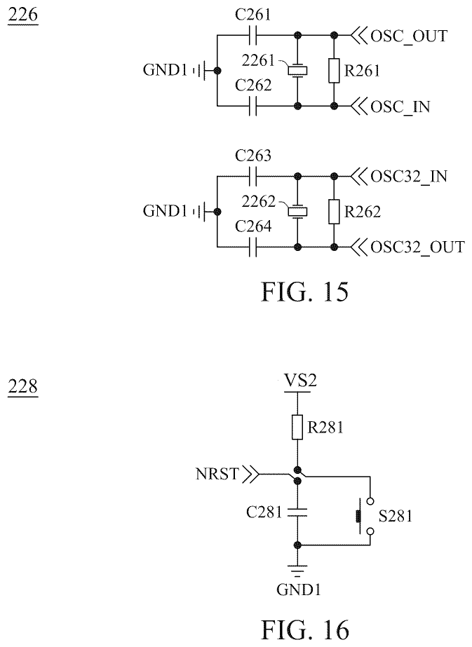

Reference is now made to FIG. 15. FIG. 15 is a schematic diagram of a crystal oscillator circuit 226, in accordance with various embodiments of the present disclosure. The crystal oscillator circuit 226 includes crystal oscillators 2261-2262. Capacitors C261-C262 are coupled between terminals of the crystal oscillators 2261 and the ground GND1. A resistor R261 is coupled between the terminals of the crystal oscillators 2261. The crystal oscillator circuit 226 is configured to generate signals OSC_OUT and OSC_IN as clock signals for the control unit 220. Similarly, capacitors C263-C264 are coupled between terminals of the crystal oscillators 2262 and the ground GND1. A resistor R262 is coupled between the terminals of the crystal oscillators 2262. The crystal oscillator circuit 226 is configured to generate signals OSC32_OUT and OSC32_IN as clock signals for the control unit 220.

Reference is now made to FIG. 16. FIG. 16 is a schematic diagram of the control unit rest circuit 228, in accordance with various embodiments of the present disclosure. For illustration, the control unit rest circuit 228 includes a resistor R281 coupled between a supply voltage VS2 and a capacitor C281. The capacitor C281 is coupled in parallel with a switch S281 between the ground GND1 and the resistor R281. In some embodiments, the control unit rest circuit 228 is configured to reset the control unit 220 in response to a reset signal NRST. In some embodiments, the control circuit 300 is further configured to transmit the reset signal NRST to the control unit rest circuit 228 to reset the control unit 220 when a new wafer carrier 40 is loaded in the load lock chamber 12A.

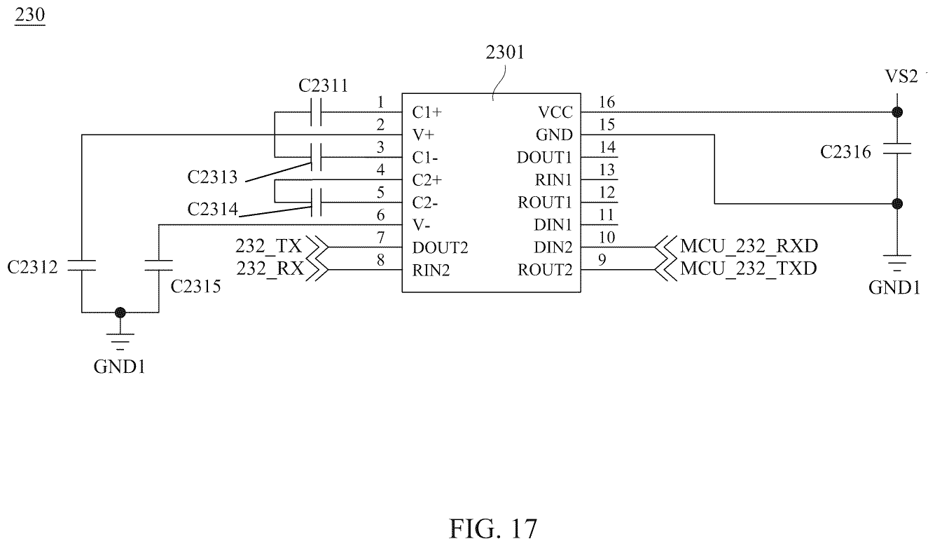

Reference is now made to FIG. 17. FIG. 17 is a schematic diagram of the communication circuit 230, in accordance with various embodiments of the present disclosure. The communication circuit 230 includes a transceiver 2301. The first to third pins of the transceiver 2301 are coupled to capacitors C2311-C2313. The fourth and fifth pins are coupled to a capacitor C2314. The sixth pin is coupled to a capacitor C2315. The seventh pin is configured to output a signal 232_TX and the eighth pin is configured to receive a signal 232_TX. The ninth pin is configured to output a signal MCU_232_TXD and the tenth pin is configured to receive a signal MCU_232_RXD. The fifteenth pin is coupled to the ground GND1 and the sixth pin is coupled to the supply voltage VS2. A capacitor C2316 is coupled between the ground GND1 and the supply voltage VS2. In some embodiments, the communication circuit 230 is configured to receive signals from the control unit 220 and transmit corresponding signals to the registered jack 240. In some embodiments, the communication circuit 230 is implemented by RS232 communication circuit.

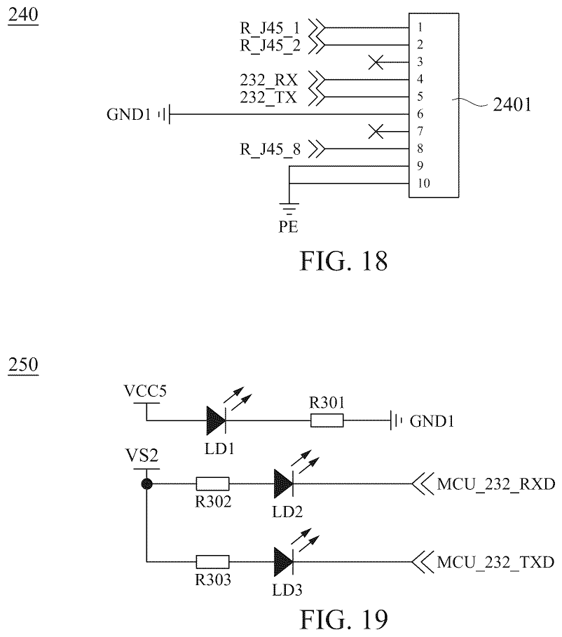

Reference is now made to FIG. 18. FIG. 18 is a schematic diagram of a registered jack 240, in accordance with various embodiments of the present disclosure. For illustration, the first and second pins of a jack 2401 in the registered jack 240 are coupled to signals R_J45_1 and R_J45_2. The fourth and fifth pins are coupled to signals 232_RX and 232_TX. The sixth pin is coupled to the ground GND1. The eighth pin is coupled to a signal R_J45_8. The ninth and tenth pins are coupled to the ground PE. In some embodiments, the registered jack 240 is configured to transmit signals to the control circuit 300 in response to signals received from the communication circuit 230. In some embodiments, the signal 232_TX includes data of time difference mentioned above.

Reference is now made to FIG. 19. FIG. 19 is a schematic diagram of the signal transmission indicator circuit 250, in accordance with various embodiments of the present disclosure. In some embodiments, the detection circuit 200 further includes a signal transmission indicator circuit 250. The signal transmission indicator circuit 250 includes a light emitting diode LD1 coupled between the supply voltage terminal VCC5 and a resistor R301. The resistor R301 is further coupled to the ground GND1. The signal transmission indicator circuit 250 further includes a light emitting diode LD2 coupled to the signal MCU_232_RXD and a resistor R302 and light emitting diode LD3 coupled to the signal MCU_232_TXD and a resistor R303. Other terminals of the resistors R302-303 are coupled to the supply voltage VS2. In some embodiments, the signal transmission indicator circuit 250 is configured to illuminate the light emitting diodes LD2-LD3 in response to transmission of the signals MCU_232_RXD MCU_232_TXD.

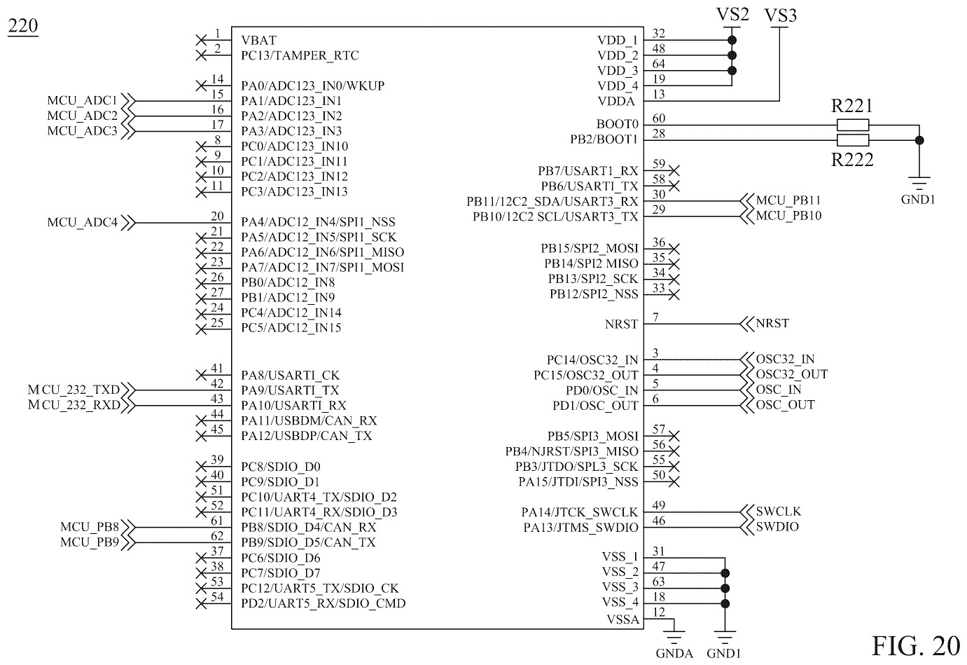

Reference is now made to FIG. 20. FIG. 20 is a schematic diagram of the control unit 220, in accordance with various embodiments of the present disclosure. In some embodiments, the control unit 220 is implemented by a microcontroller (MCU). For illustration, the third to seventh pins are coupled to the signals OSC32_IN, OSC32_OUT, OSC_IN, OSC_OUT, and NRST separately. The fifteenth to seventeenth pins are coupled to the signals MCU_ADC1-MCU_ADC3, and the twentieth pin is coupled to the signal MCU_ADC4. The twenty-ninth to thirtieth pins are coupled to signals MCU_PB8-MCU_PB11. The forty-second to forth-third pins are coupled to the signals MCU_232_TXD and MCU_232_RXD. The forty-sixth and forth-ninth pins are coupled to signals SWCLK and SWDIO. The sixty-first to sixth-second pins are coupled to the signals MCU_PB8 and MCU_232_PB9. The twelfth pin is coupled to a ground GNDA. The eighteenth, thirty-first, forth-seventh, and sixty-third pins are coupled to the ground GND1. The thirteenth pin is coupled to a supply voltage VS3. The nineteenth, thirty-second, forth-eighth, and sixty-fourth pins are coupled to the ground GND1. The twenty-eighth pin is coupled to a resistor R222. The sixtieth pin is coupled to a resistor R221. The resistors R221-R222 are further coupled to the ground GND1. In some embodiments, the control unit 220 is configured to record the time TO and the mapping times and further to calculate the time differences mentioned above.

As described above, a manufacturing system and a method are provided. Lift shaft operations undergo careful scrutiny through a real-time system that compares detected distances with standard values during wafer transfer. By examining position deviation results, adjustments can be made to malfunctioning components within the cluster-type architecture. This proactive scheme not only minimizes the risk of wafer scrap but also enhances overall manufacturing yields, cutting the cost of manufacture.

A system is provided and includes a lift shaft having a platform and an indicator extending along a shaft portion of the lift shaft. The system further includes a first sensor generating, according to a position of the indicator, a mapping start detection signal; a detection circuit detecting a voltage level of the mapping start detection signal to record a first time; and at least one second sensor generating, according to positions of a plurality of wafers in a wafer carrier on the platform, at least one mapping signal to the detection circuit. The detection circuit detects a voltage level of the mapping signal to record a second time for monitoring operations of the lift shaft.

In some embodiments, the first sensor is further configured to sense an upper portion of the indicator to pass through an opening of the first sensor to generate the mapping start detection signal have a voltage different from a ground voltage.

In some embodiments, the lift shaft is configured to move the wafer carrier to set the wafers to pass the at least one second sensor. The at least one second sensor is further configured to adjust a voltage level of the mapping signal from a first voltage to a second voltage when one of the wafers blocks the at least one second sensor.

In some embodiments, the one of the wafers is a top wafer, closest to the at least one second sensor, in the wafers.

In some embodiments, the detection circuit is further configured to generate a time difference between the first time and the second time in response to the voltage level of the mapping signal being detected to be less than a threshold voltage. The threshold voltage is greater than the second voltage.

In some embodiments, the system further includes a control circuit connected to the detection circuit, and configured to monitor the operation of the lift shaft by comparing a threshold value with a distance derived from the time difference received from the detection circuit. The control circuit is further configured to generate a deviation result indicating that the lift shaft malfunctions.

In some embodiments, the at least one second sensor includes multiple the second sensors, and the at least one mapping signal includes multiple the mapping signals. The detection circuit includes a controller unit; and multiple voltage follower circuits coupled between the first sensor and the second sensors, and configured to transmit the mapping start detection signal and the mapping signals to the controller unit. The controller unit is configured to generate a time difference between the first time and the second time.

In some embodiments, the system further includes a control circuit connected to the detection circuit, and configured to record a distance equal to that the time difference times the velocity of the lift shaft.

In some embodiments, the detection circuit is further configured to generate, in response to the at least one mapping signal, multiple time differences between the first time and multiple third times corresponding to the wafers passing the at least one second sensor. The system further includes a control circuit connected to the detection circuit, and configured to generate a position deviation result of the lift shaft in accordance with the time differences received from the detection circuit.

A method is provided, including operations of: generating, by a first sensor, a mapping start voltage; comparing, by a detection circuit, the mapping start voltage with a first voltage to record a first time when an indicator passes through the first sensor; generating, by the detection circuit, multiple time differences to a control circuit in accordance with the first time and multiple mapping signals associated with multiple wafers in a wafer carrier on a platform of a lift shaft; and generating, by the control circuit, a position deviation result of the lift shaft in accordance with the time differences to adjust the lift shaft.

In some embodiments, the method further includes triggering the detection circuit for fetching the mapping start voltage by transmitting a control signal from the control circuit in response to a number of the wafers in the wafer carrier being equal to a threshold number.

In some embodiments, the method further includes controlling the lift shaft to set the wafer carrier to pass multiple second sensors; and when the wafers block the second sensors, generating by the second sensors the mapping signals having second voltages being smaller than a threshold voltage, and when spaces between the wafers pass the second sensors, generating by the second sensors the mapping signals having third voltages being greater than the threshold voltage.

In some embodiments, generating the time differences includes recording multiple mapping times in response to the mapping signals having the second voltages; and deducting the first time from the mapping times to generate the time differences.

In some embodiments, generating the position deviation result includes calculating, according to one in the time differences and a velocity of the lift shaft, a distance; and comparing the distance with a threshold range to generate the position deviation result.

In some embodiments, generating the position deviation result further includes when the distance is out of the threshold range, generating the position deviation result indicating that the lift shaft is tilted.

In some embodiments, generating the position deviation result includes calculating, according to the time differences and a velocity of the lift shaft, multiple distances each corresponding to one in the wafers; and comparing the distances with multiple threshold ranges each corresponding to one in the wafers to generate the position deviation result.

In some embodiments, generating the position deviation result includes: calculating, according to portions in the time differences and a velocity of the lift shaft, multiple distances; and comparing the distances with multiple threshold ranges to generate the position deviation result, wherein the threshold ranges correspond to portions in the wafers.

A system is provided and includes a load lock chamber including an emitter and multiple first sensors that align with each other along a first direction; a lift shaft including: a platform on a top of a shaft portion of the lift shaft, arranged in the load lock chamber, wherein the shaft portion extends through an opening of the load lock chamber; and an indicator extending parallel to the shaft portion along a second direction; a second sensor attached to a chamber frame and having an opening aligning to a flange portion of the indicator along the first direction; and a detection circuit coupled to the first sensors and the first sensor, and configured to generate, according to a mapping start detection signal and multiple mapping signals, first time differences indicating a position deviation of the lift shaft. The mapping start detection signal corresponds to a position of the indicator, and the mapping signals correspond to a position of the platform.

In some embodiments, the indicator has C shaped cross section.

In some embodiments, the first sensors are configured to generate the mapping signals in response to multiple wafers passing the first sensors. The second sensor is configured to generate the mapping start detection signal in response to the indicator passing through the second sensor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a lift shaft comprising a platform and an indicator extending along a shaft portion of the lift shaft;
a first sensor configured to generate, according to a position of the indicator, a mapping start detection signal;
a detection circuit configured to detect a voltage level of the mapping start detection signal to record a first time; and
at least one second sensor configured to generate, according to positions of a plurality of wafers in a wafer carrier on the platform, at least one mapping signal to the detection circuit,
wherein the detection circuit is further configured to detect a voltage level of the mapping signal to record a second time for monitoring operations of the lift shaft.

2. The system of claim 1, wherein the first sensor is further configured to sense an upper portion of the indicator to pass through an opening of the first sensor to generate the mapping start detection signal have a voltage different from a ground voltage.

3. The system of claim 1, wherein the lift shaft is configured to move the wafer carrier to set the plurality of wafers to pass the at least one second sensor,
wherein the at least one second sensor is further configured to adjust a voltage level of the mapping signal from a first voltage to a second voltage when one of the plurality of wafers blocks the at least one second sensor.

4. The system of claim 3, wherein the one of the plurality of wafers is a top wafer, closest to the at least one second sensor, in the plurality of wafers.

5. The system of claim 3, wherein the detection circuit is further configured to generate a time difference between the first time and the second time in response to the voltage level of the mapping signal being detected to be less than a threshold voltage,
wherein the threshold voltage is greater than the second voltage.

6. The system of claim 5, further comprising:
a control circuit connected to the detection circuit, and configured to monitor the operation of the lift shaft by comparing a threshold value with a distance derived from the time difference received from the detection circuit,
wherein the control circuit is further configured to generate a deviation result indicating that the lift shaft malfunctions.

7. The system of claim 1, wherein the at least one second sensor includes a plurality of the second sensors, and the at least one mapping signal includes a plurality of the mapping signals;
wherein the detection circuit comprises:
a control unit; and
a plurality of voltage follower circuits coupled between the first sensor and the plurality of the second sensors, and configured to transmit the mapping start detection signal and the mapping signals to the control unit,
wherein the control unit is configured to generate a time difference between the first time and the second time.

8. The system of claim 7, wherein the system further comprises:
a control circuit connected to the detection circuit, and configured to record a distance equal to that the time difference times a velocity of the lift shaft.

9. The system of claim 1, wherein the detection circuit is further configured to generate, in response to the at least one mapping signal, a plurality of time differences between the first time and a plurality of third times corresponding to the plurality of wafers passing the at least one second sensor,
wherein the system further comprises:
a control circuit connected to the detection circuit, and configured to generate a position deviation result of the lift shaft in accordance with the plurality of time differences received from the detection circuit.

10. A method, comprising:
generating, by a first sensor, a mapping start voltage;
comparing, by a detection circuit, the mapping start voltage with a first voltage to record a first time when an indicator passes through the first sensor;
generating, by the detection circuit, a plurality of time differences to a control circuit in accordance with the first time and a plurality of mapping signals associated with a plurality of wafers in a wafer carrier on a platform of a lift shaft; and
generating, by the control circuit, a position deviation result of the lift shaft in accordance with the plurality of time differences to adjust the lift shaft.

11. The method of claim 10, further comprising:
triggering the detection circuit for fetching the mapping start voltage by transmitting a control signal from the control circuit in response to a number of the plurality of wafers in the wafer carrier being equal to a threshold number.

12. The method of claim 10, further comprising:
controlling the lift shaft to set the wafer carrier to pass a plurality of second sensors; and
when the plurality of wafers block the plurality of second sensors, generating by the plurality of second sensors the plurality of mapping signals having second voltages being smaller than a threshold voltage, and
when spaces between the plurality of wafers pass the plurality of second sensors, generating by the plurality of second sensors the plurality of mapping signals having third voltages being greater than the threshold voltage.

13. The method of claim 12, wherein generating the plurality of time differences comprises:
recording a plurality of mapping times in response to the plurality of mapping signals having the second voltages; and
deducting the first time from the plurality of mapping times to generate the plurality of time differences.

14. The method of claim 10, wherein generating the position deviation result comprises:
calculating, according to one in the plurality of time differences and a velocity of the lift shaft, a distance; and
comparing the distance with a threshold range to generate the position deviation result.

15. The method of claim 14, wherein generating the position deviation result further comprises:
when the distance is out of the threshold range, generating the position deviation result indicating that the lift shaft is tilted.

16. The method of claim 10, wherein generating the position deviation result comprises:
calculating, according to the plurality of time differences and a velocity of the lift shaft, a plurality of distances each corresponding to one in the plurality of wafers; and
comparing the plurality of distances with a plurality of threshold ranges each corresponding to one in the plurality of wafers to generate the position deviation result.

17. The method of claim 10, wherein generating the position deviation result comprises:
calculating, according to portions in the plurality of time differences and a velocity of the lift shaft, a plurality of distances; and
comparing the plurality of distances with a plurality of threshold ranges to generate the position deviation result, wherein the plurality of threshold ranges correspond to portions in the plurality of wafers.

18. A system, comprising:
a load lock chamber comprising an emitter and a plurality of first sensors that align with each other along a first direction;
a lift shaft comprising:
a platform on a top of a shaft portion of the lift shaft, arranged in the load lock chamber, wherein the shaft portion extends through an opening of the load lock chamber; and
an indicator extending parallel to the shaft portion along a second direction;
a second sensor attached to a chamber frame and having an opening aligning to a flange portion of the indicator along the first direction; and
a detection circuit coupled to the plurality of first sensors and the first sensor, and configured to generate, according to a mapping start detection signal and a plurality of mapping signals, first time differences indicating a position deviation of the lift shaft,
wherein the mapping start detection signal corresponds to a position of the indicator, and the mapping signals correspond to a position of the platform.

19. The system of claim 18, wherein the indicator has C shaped cross section.

20. The system of claim 18, wherein the plurality of first sensors are configured to generate the mapping signals in response to a plurality of wafers passing the plurality of first sensors,
wherein the second sensor is configured to generate the mapping start detection signal in response to the indicator passing through the second sensor.
